(19) United States
(12) Patent Application Publication
(10) Pub. No.: US 2024/0092810 A1
(43) Pub. Date: Mar. 21, 2024

(54) COMPOSITIONS FOR EXTREME ULTRAVIOLET LITHOGRAPHY AND RELATED METHODS

(71) Applicant: ENTEGRIS, INC., Billerica, MA (US)

(72) Inventors: Claudia Fafard, New Milford, CT (US); David M. Ermert, Danbury, CT (US); Thomas M. Cameron, Newtown, CT (US)

(21) Appl. No.: 18/240,254

(22) Filed: Aug. 30, 2023

Related U.S. Application Data
(60) Provisional application No. 63/461,784, filed on Apr. 25, 2023.
(60) Provisional application No. 63/403,397, filed on Sep. 2, 2022.

(51) Int. Cl. C07F 7/22

(52) U.S. Cl. CPC C07F 7/2224

(57) ABSTRACT

Mono-substituted tin silanolate compounds and related methods are provided. A method comprises contacting a mono-substituted tin (IV) compound with a silanolate reactant to form a mono-substituted tin silanolate compound. A composition comprises a mono-substituted tin silanolate compound.

### FIELD

The present disclosure relates to compositions useful for extreme ultraviolet (EUV) lithography and related applications, and related methods.

### BACKGROUND

Some precursors are useful in the manufacture of microelectronic devices. The manufacture of such devices can involve use of extreme ultraviolet (EUV) lithography to form thin films.

### SUMMARY

Some embodiments relate to a compound of Formula I: AₙM(X)₄₋ₙ(I), wherein: M is Sn; n is 0, 1, 2, 3, or 4; and A is an alkyl, alkenyl, alkynyl, carboxylate, enolate, ester, imide, alkoxide, cyclopentadienyl, ether, nitrile, cyano, isocyanate, or combinations thereof.

Some embodiments relate to a method comprising contacting a mono-substituted tin (IV) compound with a silanolate reactant to form a mono-substituted tin silanolate compound; wherein the mono-substituted tin (IV) compound comprises a compound of the formula: RSnQ₃, where: R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; Q is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; wherein the silanolate reactant comprises a compound of the formula: M(OSiR²₃)ₙ, where: M is an alkali metal cation, an alkaline earth metal cation, a transition metal cation, or a post-transition metal cation; R² is independently at least one of a hydrogen, a halide, an alkyl, an alkenyl, an alkynyl, a cycloalkyl, an aryl, an aralkyl, an alkaryl, or a haloalkyl; n is 1 to 4.

Some embodiments relate to a composition comprising: a mono-substituted tin silanolate compound of the formula: RSn(OSiR²₃)₃, where: R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; and R² is independently at least one of a hydrogen, a halide, an alkyl, an alkenyl, an alkynyl, a cycloalkyl, an aryl, an aralkyl, an alkaryl, or a haloalkyl.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for producing a mono-substituted tin silanolate compound, according to some embodiments.

FIG. 2 depicts a schematic sectional view of a non-limiting embodiment of an ampoule, according to some embodiments.

FIG. 3 is a thermogravimetric analysis (TGA) of iPrSn(OSi(CH₃)₃)₃, according to some embodiments.

FIG. 4 is a thermogravimetric analysis (TGA) of VinylSn(OSi(CH₃)₃)₃, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “aliphatic hydrocarbon” refers to a monovalent or polyvalent aliphatic hydrocarbon radical. The term includes, for example and without limitation, at least one of monovalent alkyl radicals, polyvalent alkyl radicals, monovalent alkenyl radicals, polyvalent alkenyl radicals, monovalent alkynyl radicals, polyvalent alkynyl radicals, or any combination thereof. The term polyvalent includes, for example and without limitation, at least one of divalent radicals, trivalent radicals, tetravalent radicals, or any combination thereof, among other multivalent radicals. Non-limiting examples of aliphatic hydrocarbons include at least one of a monovalent alkyl radical, a divalent alkyl radical, a trivalent alkyl radical, or a tetravalent alkyl radical. In some embodiments, the aliphatic hydrocarbon does not comprise a heteroatom. In some embodiments, the aliphatic hydrocarbon does not comprise any cyclic compound, such as, for example and without limitation, a cycloalkane.

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁° alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments, the term “alkyl” refers generally to alkyls, alkenyls, alkynyls, and/or cycloalkyls.

As used herein, the term “alkenyl” refers to a hydrocarbyl having from 1 to 30 carbon atoms and at least one carbon-carbon double bond. In some embodiments, the alkenyl comprises or is selected from the group consisting of at least one of a C₁-C₃₀ alkenyl, C₁-C₂₉ alkenyl, C₁-C₂₈ alkenyl, C₁-C₂₇ alkenyl, C₁-C₂₇ alkenyl, C₁-C₂₆ alkenyl, C₁-C₂₅ alkenyl, C₁-C₂₄ alkenyl, C₁-C₂₃ alkenyl, C₁-C₂₂ alkenyl, C₁-C₂₁ alkenyl, C₁-C₂₀ alkenyl, C₁-C₁₉ alkenyl, C₁-C₁₈ alkenyl, C₁-C₁₇ alkenyl, C₁-C₁₆ alkenyl, C₁-C₁₅ alkenyl, C₁-C₁₄ alkenyl, C₁-C₁₃ alkenyl, C₁-C₁₂ alkenyl, C₁-C₁₁ alkenyl, C₁-C₁₀ alkenyl, a C₁-C₉ alkenyl, a C₁-C₈ alkenyl, a C₁-C₇ alkenyl, a C₁-C₆ alkenyl, a C₁-C₅ alkenyl, a C₁-C₄ alkenyl, a C₁-C₃ alkenyl, a C₁-C₂ alkenyl, a C₂-C₃₀ alkenyl, a C₃-C₃₀ alkenyl, a C₄-C₃₀ alkenyl, a C₅-C₃₀ alkenyl, a C₆-C₃₀ alkenyl, a C₇-C₃₀ alkenyl, a C₈-C₃₀ alkenyl, a C₉-C₃₀ alkenyl, a C₁₀-C₃₀ alkenyl, a C₁₁-C₃₀ alkenyl, a C₁₂-C₃₀ alkenyl, a C₁₃-C₃₀ alkenyl, a C₁₄-C₃₀ alkenyl, a C₁₅-C₃₀ alkenyl, a C₁₆-C₃₀ alkenyl, a C₁₇-C₃₀ alkenyl, a C₁₈-C₃₀ alkenyl, a C₁₉-C₃₀ alkenyl, a C₂₀-C₃₀ alkenyl, a C₂₁-C₃₀ alkenyl, a C₂₂-C₃₀ alkenyl, a C₂₃-C₃₀ alkenyl, a C₂₄-C₃₀ alkenyl, a C₂₅-C₃₀ alkenyl, a C₂₆-C₃₀ alkenyl, a C₂₇-C₃₀ alkenyl, a C₂₈-C₃₀ alkenyl, a C₂₉-C₃₀ alkenyl, a C₂-C₁₀ alkenyl, a C₃-C₁₀ alkenyl, a C₄-C₁₀ alkenyl, a C₅-C₁₀ alkenyl, a C₆-C₁₀ alkenyl, a C₇-C₁₀ alkenyl, a C₈-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₃-C₅ alkenyl, or any combination thereof. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “alkynyl” refers to a hydrocarbyl having from 1 to 30 carbon atoms and at least one carbon-carbon triple bond. In some embodiments, the alkynyl comprises or is selected from the group consisting of at least one of a C₁-C₃₀ alkynyl, C₁-C₂₉ alkynyl, C₁-C₂₈ alkynyl, C₁-C₂₇ alkynyl, C₁-C₂₇ alkynyl, C₁-C₂₆ alkynyl, C₁-C₂₅ alkynyl, C₁-C₂₄ alkynyl, C₁-C₂₃ alkynyl, C₁-C₂₂ alkynyl, C₁-C₂₁ alkynyl, C₁-C₂₀alkynyl, C₁-C₁₉ alkynyl, C₁-C₁₈ alkynyl, C₁-C₁₇ alkynyl, C₁-C₁₆ alkynyl, C₁-C₁₅ alkynyl, C₁-C₁₄ alkynyl, C₁-C₁₃ alkynyl, C₁-C₁₂ alkynyl, C₁-C₁₁ alkynyl, C₁-C₁₀ alkynyl, a C₁-C₉ alkynyl, a C₁-C₈ alkynyl, a C₁-C₇ alkynyl, a C₁-C₆ alkynyl, a C₁-C₅ alkynyl, a C₁-C₄ alkynyl, a C₁-C₃ alkynyl, a C₁-C₂ alkynyl, a C₂-C₃₀ alkynyl, a C₃-C₃₀ alkynyl, a C₄-C₃₀ alkynyl, a C₅-C₃₀ alkynyl, a C₆-C₃₀ alkynyl, a C₇-C₃₀ alkynyl, a C₈-C₃₀ alkynyl, a C₉-C₃₀ alkynyl, a C₁₀-C₃₀ alkynyl, a C₁₁-C₃₀ alkynyl, a C₁₂-C₃₀ alkynyl, a C₁₃-C₃₀ alkynyl, a C₁₄-C₃₀ alkynyl, a C₁₅-C₃₀ alkynyl, a C₁₆-C₃₀ alkynyl, a C₁₇-C₃₀ alkynyl, a C₁₈-C₃₀ alkynyl, a C₁₉-C₃₀ alkynyl, a C₂₀-C₃₀ alkynyl, a C₂₁-C₃₀ alkynyl, a C₂₂-C₃₀ alkynyl, a C₂₃-C₃₀ alkynyl, a C₂₄-C₃₀ alkynyl, a C₂₅-C₃₀ alkynyl, a C₂₆-C₃₀ alkynyl, a C₂₇-C₃₀ alkynyl, a C₂₈-C₃₀ alkynyl, a C₂₉-C₃₀ alkynyl, a C₂-C₁₀ alkynyl, a C₃-C₁₀ alkynyl, a C₄-C₁₀ alkynyl, a C₅-C₁₀ alkynyl, a C₆-C₁₀ alkynyl, a C₇-C₁₀ alkynyl, a C₈-C₁₀ alkynyl, a C₂-C₉ alkynyl, a C₂-C₈ alkynyl, a C₂-C₇ alkynyl, a C₂-C₆ alkynyl, a C₂-C₅ alkynyl, a C₃-C₅ alkynyl, or any combination thereof. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “cycloalkyl” refers to a non-aromatic carbocyclic ring having from 3 to 8 carbon atoms in the ring. The term includes a monocyclic non-aromatic carbocyclic ring and a polycyclic non-aromatic carbocyclic ring. The term “monocyclic,” when used as a modifier, refers to a cycloalkyl having a single cyclic ring structure. The term “polycyclic,” when used as a modifier, refers to a cycloalkyl having more than one cyclic ring structure, which may be fused, bridged, spiro, or otherwise bonded ring structures. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “aryl” refers to a monocyclic or polycyclic aromatic hydrocarbon. The number of carbon atoms of the aryl may be in a range of 5 carbon atoms to 100 carbon atoms. In some embodiments, the aryl has 5 to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. In some embodiments, the aryl is —C₆H₅.

As used herein, the term “amino” and/or “amine” refer to a functional group of formula —N(R^{a}R^{b}), wherein R^{a} and R^{b} are independently a hydrogen, an alkyl (as defined herein), or a silyl (as defined herein), or R^{a} and R^{b} are bonded to each other to form a C₃-C₂₀ N-heterocycle. In some embodiments, the amino may comprise an alkylamino or a dialkylamino. In some embodiments, the amino may comprise at least one of methylamino, dimethylamino, ethylamino, diethylamino, isopropylamino, di-isopropylamino, butylamino, sec-butylamino, tert-butylamino, di-sec-butylamino, isobutylamino, di-isobutylamino, di-tert-pentylamino, ethylmethylamino, isopropyl-n-propylamino, or any combination thereof. Examples of the alkylaminos may include, without limitation, one or more of the following: primary alkylaminos, such as, for example and without limitation, methylamino, ethylamino, n-propylamino, isopropylamino, n-butylamino, sec-butylamino, isobutylamino, t-butylamino, pentylamino, 2-aminopentane, 3-aminopentane, 1-amino-2-methylbutane, 2-amino-2-methylbutane, 3-amino-2-methylbutane, 4-amino-2-methylbutane, hexylamino, 5-amino-2-methylpentane, heptylamino, octylamino, nonylamino, decylamino, undecylamino, dodecylamino, tridecylamino, tetradecylamino, pentadecylamino, hexadecylamino, heptadecylamino, and octadecylamino; and secondary alkylaminos, such as, for example and without limitation, dimethylamino, diethylamino, dipropylamino, diisopropylamino, dibutylamino, diisobutylamino, di-sec-butylamino, di-t-butylamino, dipentylamino, dihexylamino, diheptylamino, dioctylamino, dinonylamino, didecylamino, methylethylamino, methylpropylamino, methylisopropylamino, methylbutylamino, methylisobutylamino, methyl-sec-butylamino, methyl-t-butylamino, methylamylamino, methylisoamylamino, ethylpropylamino, ethylisopropylamino, ethylbutylamino, ethylisobutylamino, ethyl-sec-butylamino, ethylamino, ethylisoamylamino, propylbutylamino, and propylisobutylamino.

As used herein, the term “alkoxy” refers to a functional group of formula —OR^{c}, wherein R^{c} is an alkyl (as defined herein), a silylalkyl, a cycloalkyl, or an aryl. In some embodiments, the alkoxy may comprise, consist of, or consist essentially of, or may selected from the group consisting of, at least one of methoxy, ethoxy, methoxy, ethoxy, n-propoxy, 1-methylethoxy (isopropoxy), n-butoxy, iso-butoxy, sec-butoxy, tert-butoxy, or any combination thereof.

As used herein, the term “silyl” refers to a functional group of formula —Si(R^{e}R^{f}R^{g}), where each of R^{e}, R^{f}, and R^{g} is independently a hydrogen or an alkyl, as defined herein. In some embodiments, the silyl is a functional group of formula —SiH₃. In some embodiments, the silyl is a functional group of formula —SiReH₂, where R^{e} is not hydrogen. In some embodiments, the silyl is a functional group of formula —SiR^{e}R^{f}H, where R^{e} and R^{f} are not hydrogen. In some embodiments, the silyl is a functional group of the formula —Si(R^{e}R^{f}R^{g}), where R^{e}, R^{f}, and R^{g} are not hydrogen. In some embodiments, the silyl is a functional group of formula —Si(CH₃)₃.

As used herein, the term “alkoxyalkyl” refers to an alkyl as defined herein, wherein at least one of the hydrogen atoms of the alkyl is replaced with an alkoxy as defined herein. In some embodiments, the term “alkoxyalkyl” refers to a functional group of formula —(alkyl)OR^{a}, wherein the alkyl is defined above and wherein the R^{a} is defined above. In some embodiments, the alkoxyalkyl is a functional group of formula —(CH₂)ₙOR^{a}, where n is 1 to 10 and R^{a} is defined above. In some embodiments, the alkoxyalkyl is a functional group of the formula —CH₂CH₂OCH₃.

As used herein, the term “aralkyl” refers to an alkyl as defined herein, wherein at least one of the hydrogen atoms of the alkyl is replaced with an aryl as defined herein. In some embodiments, the term “aralkyl” refers to a functional group of formula—(alkyl)(aryl), wherein the alkyl is defined herein and the aryl is defined herein. In some embodiments, the aralkyl is —CH₂(C₆H₅).

As used herein, the term “aminoalkyl” refers to an alkyl as defined herein, wherein at least one of the hydrogen atoms of the alkyl is replaced with an amino as defined herein. In some embodiments, the term “aminoalkyl” refers to a functional group of formula —(alkyl)N(R^{b}R^{c}R^{d}), wherein the alkyl is defined above and wherein R^{b}, R^{c}, and R^{d} are defined above. In some embodiments, the aminoalkyl is —CH₂N(CH₃)₂. In some embodiments, the aminoalkyl is —(CH₂)₃N(CH₃)₂. In some embodiments, the aminoalkyl is aminomethyl (—CH₂NH₂). In some embodiments, the aminoalkyl is N,N-dimethylaminoethyl (—CH₂CH₂N(CH₃)₂). In some embodiments, the aminoalkyl is 3-(N-cyclopropylamino)propyl (—CH₂CH₂CH₂NH—Pr).

As used herein, the term “silylalkyl” refers to an alkyl as defined herein, wherein at least one of the hydrogen atoms of the alkyl is replaced with a silyl as defined herein. In some embodiments, the term “silylalkyl” refers to a functional group of formula —(alkyl)Si(R^{e}R^{f}R^{g}), wherein the alkyl is defined above and wherein R^{e}, R^{f}, and R^{g} are defined above. In some embodiments, the silylalky is a functional group of formula —(CH₂)ₘSi(R^{e}R^{f}R^{g}), where m is 1 to 10 and where R^{e}, R^{f}, and R^{g} are defined above. In some embodiments, the silylalkyl is a functional group of formula —CH₂Si CH₃)₃.

As used herein, the term “haloalkyl” refers to an alkyl as defined here, wherein at least one of the hydrogen atoms of the alkyl is replaced with a halide as defined herein. In some embodiments, the haloalkyl comprises a fluoroalkyl. In some embodiments, the fluoroalkyl comprises at least one of —CH₂CF₃, —CH(CF₃)₂, —CH₂F, —CH₂CH₂F, —CF₃, —CF₂CF₃, or any combination thereof.

As used herein, the term “halide” refers to a —Cl, —Br, —I, or —F.

As used herein, the term “metal cation” refers to at least one of a alkali metal cation, an alkaline earth metal cation, a transition metal cation, a post-transition metal cation, or any combination thereof. In some embodiments, the metal cation comprises a lithium cation, a sodium cation, a potassium cation, a rubidium cation, a cesium cation, a francium cation, a beryllium cation, a magnesium cation, a calcium cation, a strontium cation, a barium cation, a radium cation, a scandium cation, a titanium cation, a vanadium cation, a chromium cation, a manganese cation, an iron cation, a cobalt cation, a nickel cation, a copper cation, a zinc cation, a yttrium cation, a zirconium cation, a niobium cation, a molybdenum cation, a technetium cation, a ruthenium cation, a rhodium cation, a palladium cation, a silver cation, a cadmium cation, a hafnium cation, a tantalum cation, a tungsten cation, a rhenium cation, an osmium cation, an iridium cation, a platinum cation, a gold cation, a mercury cation, an aluminum cation, a gallium cation, an indium cation, tin cation, a thallum cation, a lead cation, a bismuth cation, or a polonium cation. The charge(s) of the metal cations are known and, for simplicity, thus are not repeated here; however, it will be appreciated that the metal cations can have any known charge. For example, in some embodiments, the metal cation comprises Li⁺, Na⁺, K⁺, Rb⁺, Cs⁺, Mg²⁺, Ca²⁺, Sr²⁺, Ba²⁺, Zn²⁺, Sn²⁺, or Sn⁴⁺. In some embodiments, the metal cation is Sn²⁺. In some embodiments, the metal cation is Sn⁴⁺.

Some embodiments relate to precursors and related methods. At least some of these embodiments relate to precursors useful in the fabrication of microelectronic devices, including semiconductor devices, and the like. For example, the precursors can be used to form silicon-containing films by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

Some embodiments relate to compounds, such as compounds used in applications for tin-oxide film growth, extreme ultraviolet lithography, plastics, or radiation sensitive films. The compounds include precursors that can be used to generate the photoresist, e.g., the photoresist in processes related to the electronic industry.

Some embodiments relate to compounds used in applications, such as extreme ultraviolet lithography applications. The compounds include precursors targeting extreme ultraviolet lithography applications, such as extreme ultraviolet hard mask applications. The compounds of the present disclosure can be used as a precursor for materials to be used as hard mask materials in extreme ultraviolet lithography applications.

In some embodiments, the present disclosure includes compounds of Formula I: AₙM(X)₄₋ₙ. In some embodiments, M is Sn, and n is 0, 1, 2, 3, or 4. In some embodiments, “A” is an alkyl, alkenyl, alkynyl, carboxylate, enolate, ester, imide, alkoxide, cyclopentadienyl, ether, nitrile, cyano, isocyanate, or combinations thereof.

In some embodiments, the compound is chosen from one of the following:

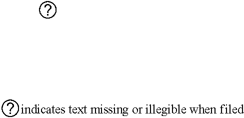

In some embodiments, A of Formula I is an enolate. In some embodiments, the enolate comprises a structure of:

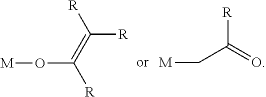

In some embodiments, M may comprise a metal in a solid form. For example, in some embodiments, M may comprise a metal in a form of a powder, a particle, or a tablet. In some embodiments, M is Sn.

In some embodiments, R is hydrogen or a C₁-C₆ alkyl group. For example, in some embodiments, the alkyl is saturated (e.g., single bonds). In some embodiments, the alkyl is unsaturated (e.g., double bonds and/or triple bonds). In some embodiments, the alkyl is linear. In some embodiments, the alkyl is branched. In some embodiments, the alkyl is substituted. In some embodiments, the alkyl is unsubstituted. In some embodiments, the alkyl may comprise, consist of, or consist essentially of, or may be selected from the group consisting of, at least one of a C₁-C₆ alkyl, C₁-C₅ alkyl, a C₁-C₄ alkyl, a C₁-C₃ alkyl, a C₁-C₂ alkyl, a C₁ alkyl, fluorine substituted C₁-C₆ alkyl group, or any combinations thereof.

In some embodiments, A and X are the same. For example, A and X can be of the same class/family of ligands. In some embodiments, A and X are both an alkyl, alkenyl, alkynyl, carboxylate, enolate, ester, imide, alkoxide, cyclopentadienyl, ether, or combinations thereof (that is, A and X are the same combination of the preceding compounds).

In some embodiments, A of Formula I is a cyclopentadienyl with the following formula

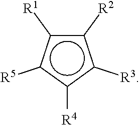

In some embodiments, each R¹-R⁵ is independently selected from hydrogen or a C₁-C₆ alkyl group. In some embodiments, the C₁-C₆ alkyl group is branched or unbranched (linear). In some embodiments, the C₁-C₆ alkyl group is substituted or unsubstituted. For example, in some embodiments, the alkyl is saturated (e.g., single bonds). In some embodiments, the alkyl is unsaturated (e.g., double bonds and/or triple bonds). In some embodiments, the alkyl may comprise, consist of, or consist essentially of, or may be selected from the group consisting of, at least one of a C₁-C₆ alkyl, a C₁-C₅ alkyl, a C₁-C₄ alkyl, a C₁-C₃ alkyl, a C₁-C₂ alkyl, a C₁ alkyl, or any combinations thereof.

In some embodiments, n of Formula I is 1. In some embodiments, (X)₄₋ₙ of Formula I is (NR₂)₃, (OR)₃, (CCR)₃, (CRCR₂)₃, or H₃. In some embodiments, R is hydrogen or a C₁-C₆ alkyl group. In some embodiments, X can include a halide such as fluoride (F⁻), chloride (Cl⁻), bromide (Br⁻), and iodide (I⁻). In some embodiments, X of Formula I is NR₂, OR, CCR, CRCR₂, F, Cl, Br, I, or H. In some embodiments, R is hydrogen or a C₁-C₆ alkyl group. In some embodiments, R is hydrogen, a C₁-C₆ alkyl group, or a fluorine substituted C₁-C₆ alkyl group. In some embodiments, the fluorine substituted C₁-C₆ alkyl group is CH₂CF₃.

In some embodiments, X is a ligand. In some embodiments, the ligand is cyclopentadienyl, nitrile, or cyanide.

In some embodiments, A comprises a substituted fluorinated group. In some embodiments, the substituted fluorinated group comprises —OCH₂CF₃, —OCH(CF₃)₂, —O₂CCF₃, or —OC(CF₃)CH₂.

In some embodiments, A with the substituted fluorinated group comprises fluorinate ether, fluorinated carboxylate, or fluorinated alkoxide.

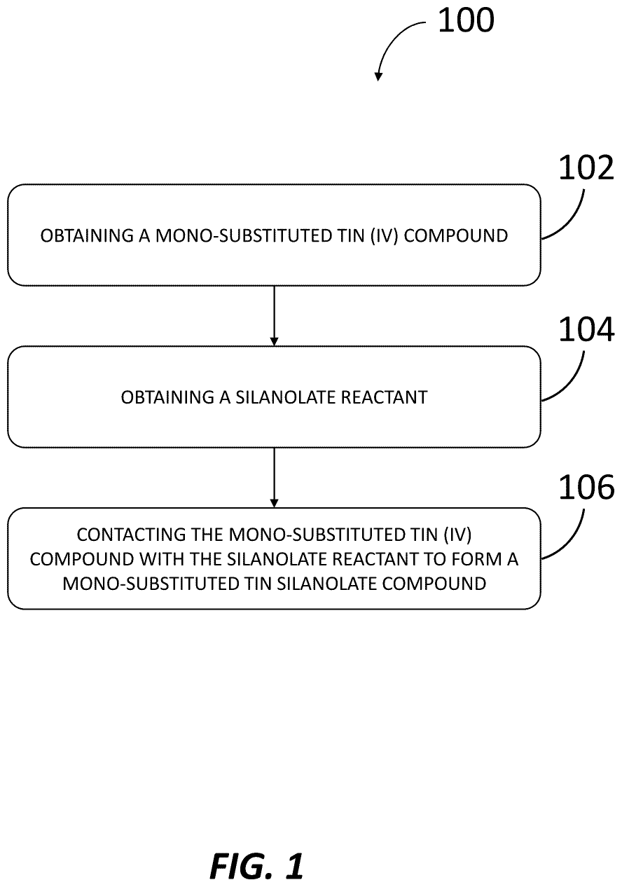

FIG. 1 is a flowchart of a method 100 for producing a mono-substituted tin silanolate compound, according to some embodiments. As shown in FIG. 1, the method 100 for producing the mono-substituted tin silanolate compound comprises one or more of the following steps: obtaining 102 a mono-substituted tin (IV) compound, obtaining 104 a silanolate reactant; and contacting 106 the mono-substituted tin (IV) compound with the silanolate reactant to form a mono-substituted tin silanolate compound.

At step 102, the method 100 comprises obtaining a mono-substituted tin (IV) compound. In some embodiments, the mono-substituted tin (IV) compound comprises a compound of the formula:

RSnQ₃,

where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; and
Q is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof.

In some embodiments, R is at least one of —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

In some embodiments, R is at least one of —CH₂CF₃, —CH(CF₃)₂, —CH₂F, —CH₂CH₂F, —CF₃, —CF₂CF₃, or any combination thereof. In some embodiments, R is at least one of —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

In some embodiments, Q is independently at least one of —H, —Cl, —Br, —F, —I, —NR¹₂, —OR¹, —C≡CR¹, —OSiR¹₃, or any combination thereof, wherein R¹ is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof.

In some embodiments, Q is independently at least one of —Cl, —Br, —F, —I, or any combination thereof.

In some embodiments, Q is independently at least one of —H, —NR¹₂, —OR¹, —C≡CR¹, or any combination thereof, wherein R¹ is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof.

In some embodiments, Q is —OSiR¹₃, wherein R¹ is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof.

In some embodiments, R is at least one of —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof; Q is independently at least one of —H, —Cl, —Br, —F, —I, —NR¹₂, —OR¹, —C≡CR¹, —OSiR¹₃, or any combination thereof, wherein R¹ is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof.

In some embodiments, R and Q are different. In some embodiments, R and Q are the same. In some embodiments, R and at least one Q are different. In some embodiments, R and at least one Q are the same.

At step 104, the method 100 comprises obtaining a silanolate reactant. In some embodiments, the silanolate reactant comprises a compound of the formula:

M(OSiR²₃)ₙ,

where:
M is an alkali metal cation, an alkaline earth metal cation, a transition metal cation, or a post-transition metal cation;
R² is independently at least one of a hydrogen, a halide, an alkyl, an alkenyl, an alkynyl, a cycloalkyl, an aryl, an aralkyl, an alkaryl, a haloalkyl, or any combination thereof; and
n is 1 to 4.

In some embodiments, R² is independently at least one of a hydrogen, a C₁-C₁₂ alkyl, a C₁-C₁₂ alkenyl, a C₁-C₁₂ alkynyl, a phenyl, a fluoro, a chloro, a bromo, an iodo, or any combination thereof.

In some embodiments, R is isopropyl; Q is chloro; M is Na⁺; and R² is methyl. In some embodiments, R is vinyl; X is chloro; M is Na⁺; and R² is methyl.

At step 106, the method 100 comprises contacting the mono-substituted tin (IV) compound with the silanolate reactant to form a mono-substituted tin silanolate compound.

In some embodiments, the mono-substituted tin silanolate compound is formed via a substitution reaction (e.g., a substitution reaction in which at least one of the leaving groups, Q, is replaced by —OSiR²₃). In some embodiments, the contacting comprises reacting the mono-substituted tin (IV) compound with the silanolate reactant. In some embodiments, the contacting comprises mixing the mono-substituted tin (IV) compound and the silanolate reactant. In some embodiments, the contacting comprises agitating the mono-substituted tin (IV) compound and the silanolate reactant. In some embodiments, the contacting comprises adding the mono-substituted tin (IV) compound and the silanolate reactant to a reaction vessel. In some embodiments, the contacting comprises dissolving the mono-substituted tin (IV) compound and the silanolate reactant. In some embodiments, the contacting comprises combining the mono-substituted tin (IV) compound and the silanolate reactant. In some embodiments, the contacting is performed in solution.

In some embodiments, the mono-substituted tin silanolate compound is a compound of the formula:

RSn(OSiR²₃)₃,
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; and
R² is independently at least one of a hydrogen, a halide, an alkyl, an alkenyl, an alkynyl, a cycloalkyl, an aryl, an aralkyl, an alkaryl, a haloalkyl, or any combination thereof.

In some embodiments, R is at least one of —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

In some embodiments, R is at least one of —CH₂CF₃, —CH(CF₃)₂, —CH₂F, —CH₂CH₂F, —CF₃, —CF₂CF₃, or any combination thereof. In some embodiments, R is at least one of —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

In some embodiments, R² is independently at least one of a hydrogen, a C₁-C₁₂ alkyl, a C₁-C₁₂ alkenyl, a C₁-C₁₂ alkynyl, a phenyl, a fluoro, a chloro, a bromo, an iodo, or any combination thereof.

In some embodiments, the mono-substituted tin silanolate compound is a compound of the formula:

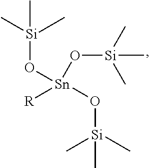

where:
R is —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, or —Si(CH₃)₃.

In some embodiments, the mono-substituted tin silanolate compound is a compound of the formula:

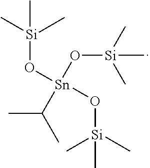

In some embodiments, the mono-substituted tin silanolate compound is a compound of the formula:

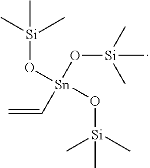

Some embodiments relate to a composition. In some embodiments, the composition comprises a mono-substituted tin silanolate compound. In some embodiments, the mono-substituted tin silanolate compound is a compound of the formula:

RSn(OSiR²₃)₃,

where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; and
R² is independently at least one of a hydrogen, a halide, an alkyl, an alkenyl, an alkynyl, a cycloalkyl, an aryl, an aralkyl, an alkaryl, a haloalkyl, or any combination thereof.

In some embodiments, R is at least one of —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

In some embodiments, R is at least one of —CH₂CF₃, —CH(CF₃)₂, —CH₂F, —CH₂CH₂F, —CF₃, —CF₂CF₃, or any combination thereof. In some embodiments, R is at least one of —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

In some embodiments, R² is independently at least one of a hydrogen, a C₁-C₁₂ alkyl, a C₁-C₁₂ alkenyl, a C₁-C₁₂ alkynyl, a phenyl, a fluoro, a chloro, a bromo, an iodo, or any combination thereof.

In some embodiments, the mono-substituted tin silanolate compound is a compound of the formula:

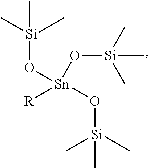

where:
R is —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, or —Si(CH₃)₃.

In some embodiments, the mono-substituted tin silanolate compound is a compound of the formula:

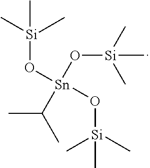

In some embodiments, the mono-substituted tin silanolate compound is a compound of the formula:

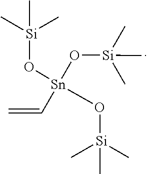

In some embodiments, a purity of the mono-substituted tin silanolate compound is at least 70%, at least 75%, at least 80%, at least 85%, at least 90%, at least 91%, at least 92%, at least 93%, at least 94%, at least 95%, at least 96%, at least 97%, at least 98%, at least 99%, at least 99.9%, at least 99.99%, at least 99.999%, at least 99.9999% or greater. In some embodiments, a purity of the mono-substituted tin silanolate compound is 70% to 95%, 75% to 95%, 80% to 95%, 85% to 95%, 90% to 95%, 70% to 90%, 70% to 85%, 70% to 80%, 70% to 75%, or any range or subrange between 70% and 95%. In some embodiments, a purity of the mono-substituted tin silanolate compound is 95% to 99.9999%, 95% to 99.999%, 95% to 99.99%, 95% to 99.9%, 95% to 99%, 95% to 98%, 95% to 97%, 95% to 96%, 96% to 99.9999%, 97% to 99.9999%, 98% to 99.9999%, 99% to 99.9999%, 99.9% to 99.9999%, 99.99% to 99.9999%, 99.999% to 99.9999%, or any range or subrange between 95% to 99.9999%.

In some embodiments, an impurity comprises a compound of the formula:

RaSn(OSiR²₃)_{b},

where:
a is 2, 3, or 4;
b is 0, 1, or 2; and
R and R² are as defined above.

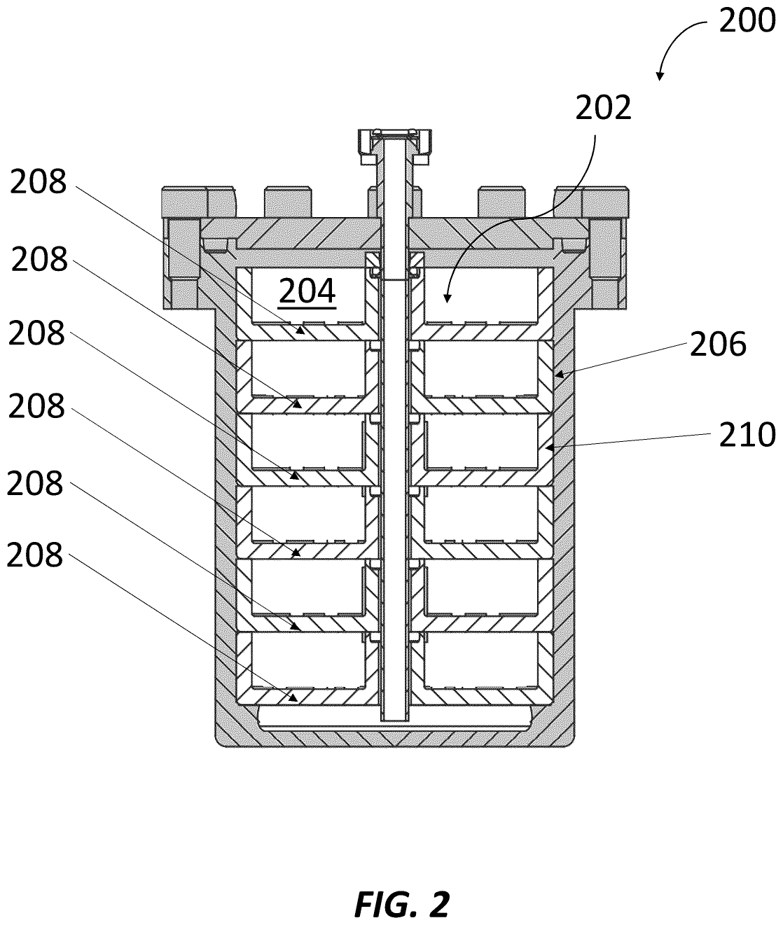

FIG. 2 depicts a schematic sectional view of a non-limiting embodiment of an ampoule 200, according to some embodiments. The ampoule 200 contains a tray assembly 202 in an inner chamber 204 of the ampoule 200. The inner chamber 204 has an inner wall surface 206. The tray assembly 202 comprises trays 208, each of which are configured to contain a vaporizable precursor. In some embodiments, the vaporizable precursor comprises any one or more of the compositions disclosed herein, including compositions comprising the mono-substituted tin silanolate compounds. Each of the trays 208 of the tray assembly 202 comprises a portion 210 which is configured to be in contact (e.g., thermal contact, physical contact, etc.) with the inner wall surface 206 of the ampoule 200. The surface-to-surface contact of the portion 210 with the inner wall surface 206 enhances heat transfer from the ampoule 200 to each tray 208 and thus from each tray 208 to the vaporizable precursor on each tray 208. Various fluid flow paths are defined within the inner chamber 204 of the ampoule 200 such that a fluid is allowed to flow through the ampoule 200 upwards, downwards, or both. The ampoule 200 is shown having a generally cylindrical inner chamber. However, it will be appreciated that the inner chamber 204 of the ampoule may have other shapes without departing from the scope of this disclosure.

### Example 1

### Synthesis of iPrSn(OSi(CH₃)₃)₃

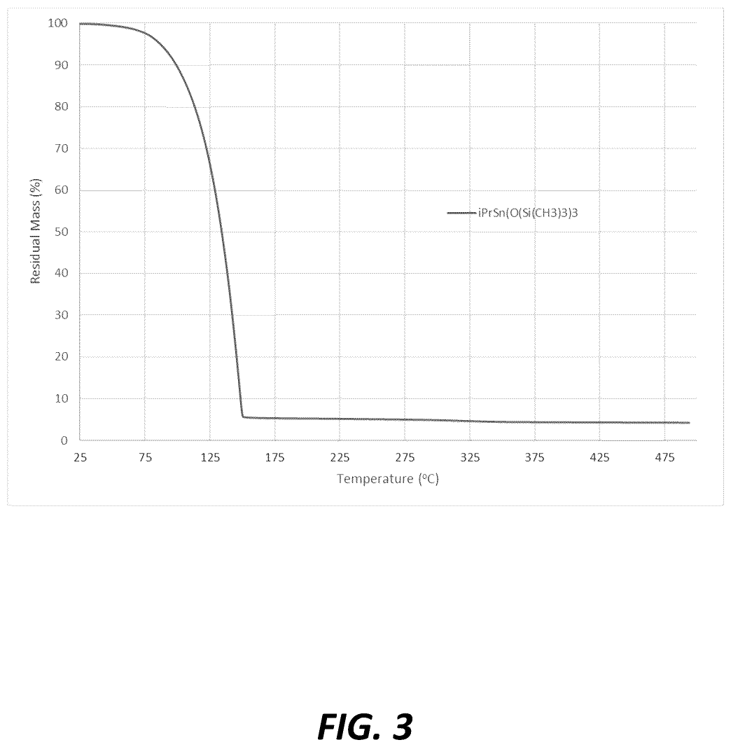

In a nitrogen-filled glovebox, iPrSnCl₃ (20.0 g, 74.5 mmol) (CAS #27440-55-7) was loaded into a 500 mL round bottom flask equipped with a magnetic stir bar and diluted with 400 mL of hexanes. NaOSi(CH₃)₃ (26.2 g, 234 mmol) (CAS #18027-10-6) was added directly to the stirred solution using a conical addition funnel over the course of one hour, resulting in an exotherm and presentation of a thick white mixture. Upon complete addition the flask was equipped with a reflux condenser cooled to −4° C. and the reaction stirred at 60° C. for 12 hours. The reaction was cooled to room temperature, the resulting thick white mixture filtered through a disposable polyethylene filter frit, the frit washed with 50 mL of hexanes, and the combined organic fractions dried under reduced pressure to yield iPrSn(OSi(CH₃)₃)₃ a colorless liquid. mass: 19.27 g, 60.1% yield. The product was loaded into a 50 mL Schlenk flask equipped with a magnetic stir bar and placed on a Schlenk line under N₂ working gas, and equipped with a short-path distillation head outfitted with a thermometer and 50 mL collection flask. The distillation apparatus was placed under reduced pressure, the condenser warmed to 25° C., and the collection flask cooled using an ice bath. The product was purified by distillation at 40-42° C. and pressure of 100-110 mTorr to yield iPrSn(O(Si(CH₃)₃)₃ as a colorless liquid. Mass of distilled product: 15.11 g, 47.3% distilled yield. Purity by ¹H- and ¹¹⁹Sn-NMR is >99.9%. ¹H{¹³C}-NMR (400 MHz, C₆D₆, 298K): 0.21 (s, 27H); 1.12 (d, 6H); 1.63 (sept, 1H) ppm; ¹³C{¹H}-NMR (100 MHz, C₆D₆, 298K): 3.34; 19.65; 26.84 ppm; ¹¹⁹Sn{¹H}-NMR (149 MHz, C₆D₆, 298K): −267.60 ppm. ²⁹Si{¹H}-NMR (79 MHz, C₆D₆, 298K): 12.08 ppm. FIG. 3 is a thermogravimetric analysis (TGA) of iPrSn(OSi(CH₃)₃)₃, according to some embodiments.

### Example 2

### Synthesis of VinylSn(OSi(CH₃)₃)₃

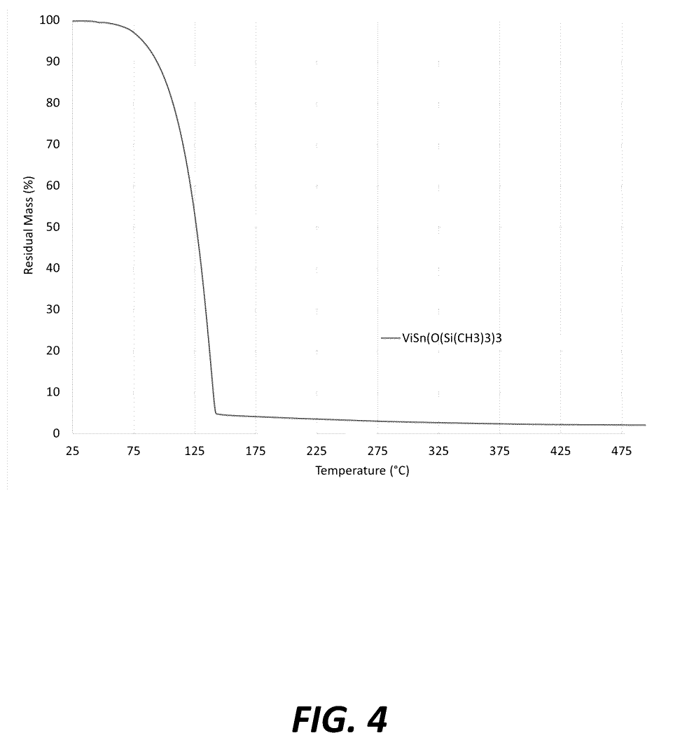

In a nitrogen filled glovebox, VinylSnCl₃ (1.0 g, 3.96 mmol) was placed in an 40 mL amber vial equipped with a stir bar and dissolved in 10 mL of hexanes. NaOSi(CH₃)₃ (1.34 g, 12.0 mmol) (CAS #18027-10-6) was added over 5 minutes. An exotherm and solids were observed. The reaction mixture was then stirred at 60 C overnight. The following day the thick reaction mixture was filtered through a disposable polyethylene (PE) frit and the solids washed with 5 mL of hexanes. The solvent was then removed from the filtrate and washings under vacuum. A clear colorless oil was obtained and overnight some crystalline material was observed. A minimum amount of hexanes was added to dissolve the solid and the solution placed in the −35° C. freezer. White crystalline material was observed. The solution was decanted off and the crystalline solid washed with 2 mL of cold hexanes and then dried under vacuum. VinylSn(OSi(CH₃)₃)₃ (1.2 g, 73% yield, Purity by ¹¹⁹Sn 83%) was collected as a crystalline white solid. ¹H{¹³C}-NMR (400 MHz, C₆D₆, 298K): 0.23 (s, 27H); 5.76 (2H); 5.8-6.6 (1H) ppm; ¹³C{¹H}-NMR (100 MHz, C₆D₆, 298K): 3.24; 131.07; 139.99 ppm; ¹¹⁹Sn{¹H}-NMR (149 MHz, C₆D₆, 298K): −300.8 ppm. FIG. 4 is a thermogravimetric analysis (TGA) of VinylSn(OSi(CH₃)₃)₃, according to some embodiments.

Aspects

Various Aspects are described below. It is to be understood that any one or more of the features recited in the following Aspect(s) can be combined with any one or more other Aspect(s).

Aspect 1. A compound of Formula I: AₙM(X)₄₋ₙ(I), wherein: M is Sn; n is 0, 1, 2, 3, or 4; and A is an alkyl, alkenyl, alkynyl, carboxylate, enolate, ester, imide, alkoxide, cyclopentadienyl, ether, nitrile, cyano, isocyanate, or combinations thereof.
Aspect 2. The compound of Aspect 1, wherein A is an enolate.
Aspect 3. The compound of Aspect 2, wherein the enolate comprises a structure of:

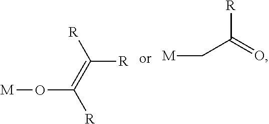

wherein M is Sn.
Aspect 4. The compound of Aspect 3, wherein R is hydrogen or a C₁-C₆ alkyl group.
Aspect 5. The compound of Aspect 1, wherein A is a cyclopentadienyl with the following formula

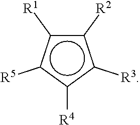

Aspect 6. The compound of Aspect 5, wherein each R¹-R⁵ is independently selected from hydrogen or a C₁-C₆ alkyl group.
Aspect 7. The compound of Aspect 6, wherein the C₁-C₆ alkyl group is branched or unbranched.
Aspect 8. The compound of Aspect 6, wherein the C₁-C₆ alkyl group is substituted or unsubstituted.
Aspect 9. The compound as in any of the preceding Aspects, wherein n is 1.
Aspect 10. The compound of Aspect 9, wherein (X)₄₋ₙ is (NR₂)₃, (OR)₃, (CCR)₃, (CRCR₂)₃, or H₃.
Aspect 11. The compound of Aspect 10, wherein R is hydrogen or a C₁-C₆ alkyl group.
Aspect 12. The compound as in any of the preceding Aspects, wherein X is NR₂, OR, CCR, CRCR₂, F, Cl, Br, I, or H.
Aspect 13. The compound of Aspect 12, wherein R is hydrogen, a C₁-C₆ alkyl group, or a fluorine substituted C₁-C₆ alkyl group.
Aspect 14. The compound of Aspect 13, wherein the fluorine substituted C₁-C₆ alkyl group is CH₂CF₃.
Aspect 15. The compound as in any one of Aspects 1-11, wherein X is a ligand.
Aspect 16. The compound of Aspect 15, wherein the ligand is cyclopentadienyl, nitrile, or cyanide.
Aspect 17. The compound as in any of the preceding Aspects, wherein A comprises a substituted fluorinated group.
Aspect 18. The compound of Aspect 17, wherein A with the substituted fluorinated group comprises —OCH₂CF₃, —OCH(CF₃)₂, —O₂CCF₃, or —OC(CF₃)CH₂.
Aspect 19. The compound of Aspect 17, wherein A with the substituted fluorinated group comprises fluorinate ether, fluorinated carboxylate, or fluorinated alkoxide.
Aspect 20. The compound of Aspect 1, wherein the compound is chosen from one of the following:

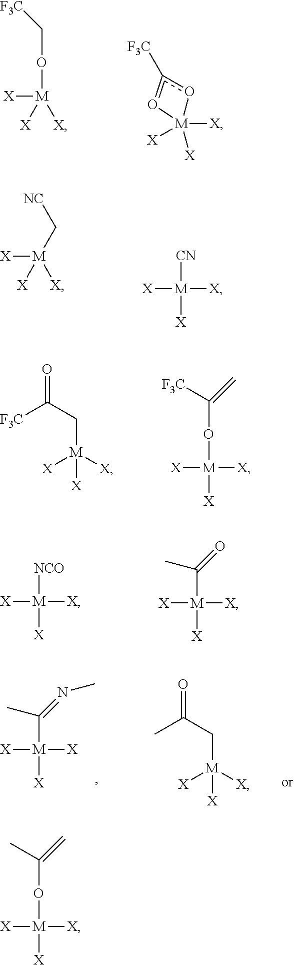

wherein M is Sn.
   Aspect 21. A method comprising:
contacting a mono-substituted tin (IV) compound with a silanolate reactant to form a mono-substituted tin silanolate compound;
   wherein the mono-substituted tin (IV) compound comprises a compound of the formula:

RSnQ₃,
where:
   R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
   Q is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
wherein the silanolate reactant comprises a compound of the formula:

M(OSiR²₃)ₙ,
where:
   M is an alkali metal cation, an alkaline earth metal cation, a transition metal cation, or a post-transition metal cation;
   R² is independently at least one of a hydrogen, a halide, an alkyl, an alkenyl, an alkynyl, a cycloalkyl, an aryl, an aralkyl, an alkaryl, or a haloalkyl;
   n is 1 to 4.
      Aspect 22. The method according to Aspect 21, wherein R is at least one of —CH₂CF₃, —CH(CF₃)₂, —CH₂F, —CH₂CH₂F, —CF₃, —CF₂CF₃, or any combination thereof.
      Aspect 23. The method according to any one of Aspects 21-22, wherein R is at least one of —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.
      Aspect 24. The method according to any one of Aspects 21-23, wherein Q is independently at least one of —H, —Cl, —Br, —F, —I, —NR¹₂, —OR¹, —C≡CR¹, —OSiR¹₃, or any combination thereof,
wherein:
   R¹ is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof.
      Aspect 25. The method according to any one of Aspects 21-24, wherein:
R is isopropyl;
Q is chloro;
M is Na⁺; and
R² is methyl.
   Aspect 26. The method according to any one of Aspects 21-25, wherein:
R is vinyl;
X is chloro;
M is Na⁺; and
R² is methyl.
   Aspect 27. The method according to any one of Aspects 21-26, wherein:
M is Li⁺, Na⁺, K⁺, Rb⁺, Cs⁺, Mg²⁺, Ca²⁺, Sr²⁺, Ba²⁺, Zn²⁺, Sn²⁺, or Sn⁴⁺.
   Aspect 28. The method according to any one of Aspects 21-27, wherein:
M is Sn⁴⁺.
   Aspect 29. The method according to any one of Aspects 21-28, wherein R² is independently at least one of a hydrogen, a C₁-C₁₂ alkyl, a C₁-C₁₂ alkenyl, a C₁-C₁₂ alkynyl, a phenyl, a fluoro, a chloro, a bromo, an iodo, or any combination thereof.
   Aspect 30. The method according to any one of Aspects 21-29, wherein the mono-substituted tin silanolate compound is a compound of the formula:

RSn(OSiR²₃)₃,
where:
   R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; and
   R² is independently at least one of a hydrogen, a halide, an alkyl, an alkenyl, an alkynyl, a cycloalkyl, an aryl, an aralkyl, an alkaryl, or a haloalkyl.
      Aspect 31. The method according to any one of Aspects 21-30, wherein the mono-substituted tin silanolate compound is a compound of the formula:
where:

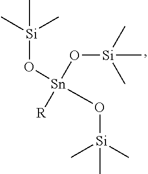

R is —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, or —Si(CH₃)₃.
   Aspect 32. The method according to any one of Aspects 21-31, wherein the mono-substituted tin silanolate compound is a compound of the formula:

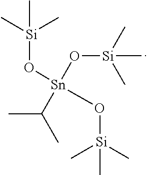

Aspect 33. The method according to any one of Aspects 21-32, wherein the mono-substituted tin silanolate compound is a compound of the formula:

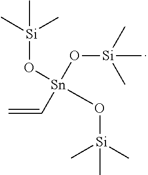

Aspect 34. A composition comprising:
a mono-substituted tin silanolate compound of the formula:

RSn(OSiR²₃)₃,
where:
   R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; and
   R² is independently at least one of a hydrogen, a halide, an alkyl, an alkenyl, an alkynyl, a cycloalkyl, an aryl, an aralkyl, an alkaryl, or a haloalkyl.
      Aspect 35. The composition according to Aspect 34, wherein the mono-substituted tin silanolate compound is a compound of the formula:

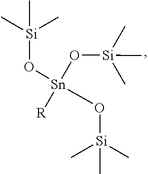

where:
   R is —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, or —Si(CH₃)₃.
      Aspect 36. The composition according to any one of Aspects 34-35, wherein the mono-substituted tin silanolate compound is a compound of the formula:

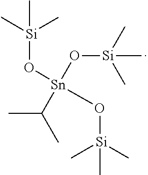

Aspect 37. The composition according to Aspect 36, wherein a purity of the mono-substituted tin silanolate compound is at least 99.9%.
Aspect 38. The composition according to any one of Aspects 34-37, wherein the mono-substituted tin silanolate compound is a silanolate compound of the formula:

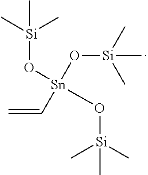

Aspect 39. The composition according to Aspect 38, wherein a purity of the mono-substituted tin silanolate compound is at least 80%.
Aspect 40. The composition according to any one of Aspects 34-39, wherein a purity of the mono-substituted tin silanolate compound is at least 99.9%.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A method comprising:
contacting a mono-substituted tin (IV) compound with a silanolate reactant to form a mono-substituted tin silanolate compound;
wherein the mono-substituted tin (IV) compound comprises a compound of the formula:
RSnQ₃,
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amide, a halide, an imide, a cyanate, a nitrile, an alkoxide, a carboxylate, an enolate, an ester, a cyclopentadienyl, or any combination thereof;
Q is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amide, a halide, an imide, a cyanate, a nitrile, an alkoxide, a carboxylate, an enolate, an ester, a cyclopentadienyl, or any combination thereof;
wherein the silanolate reactant comprises a compound of the formula:
M(OSiR²₃)ₙ,
where:
M is an alkali metal cation, an alkaline earth metal cation, a transition metal cation, or a post-transition metal cation;
R² is independently at least one of a hydrogen, a halide, an alkyl, an alkenyl, an alkynyl, a cycloalkyl, an aryl, an aralkyl, an alkaryl, or a haloalkyl;
n is 1 to 4.

2. The method of claim 1, wherein R is at least one of —CH₂CF₃, —CH(CF₃)₂, —CH₂F, —CH₂CH₂F, —CF₃, —CF₂CF₃, or any combination thereof.

3. The method of claim 1, wherein R is at least one of —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

4. The method of claim 1, wherein Q is independently at least one of —H, —Cl, —Br, —F, —I, —NR¹₂, —OR¹, —C≡CR¹, —OSiR¹₃, or any combination thereof,
wherein:
R¹ is independently at least one of a hydrogen, an alkyl, an alkenyl, an alkynyl, a cycloalkyl, an aryl, a silyl, a silylalkyl, a silanolate, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof.

5. The method of claim 1, wherein:
R is isopropyl;
Q is chloro;
M is Na⁺; and
R² is methyl.

6. The method of claim 1, wherein:
R is vinyl;
X is chloro;
M is Na⁺; and
R² is methyl.

7. The method of claim 1, wherein:
M is Li⁺, Na⁺, K⁺, Rb⁺, Cs⁺, Mg²⁺, Ca²⁺, Sr²⁺, Ba²⁺, Zn²⁺, Sn²⁺, or Sn⁴⁺.

8. The method of claim 1, wherein:
M is Sn⁴⁺.

9. The method of claim 1, wherein R² is independently at least one of a hydrogen, a C₁-C₁₂ alkyl, a C₁-C₁₂ alkenyl, a C₁-C₁₂ alkynyl, a phenyl, a fluoro, a chloro, a bromo, an iodo, or any combination thereof.

10. The method of claim 1, wherein the mono-substituted tin silanolate compound is a compound of the formula:
RSn(OSiR²₃)₃,
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; and
R² is independently at least one of a hydrogen, a halide, an alkyl, an alkenyl, an alkynyl, a cycloalkyl, an aryl, an aralkyl, an alkaryl, or a haloalkyl.

11. The method of claim 1, wherein the mono-substituted tin silanolate compound is a compound of the formula: 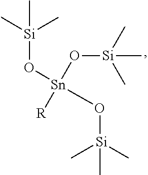
where:
R is —CH₂CF₃, —CH(CF₃)₂, —CH₂F, —CH₂CH₂F, —CF₃, —CF₂CF₃, —CH₂CN, —CN, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, or —Si(CH₃)₃.

12. The method of claim 1, wherein the mono-substituted tin silanolate compound is a compound of the formula:

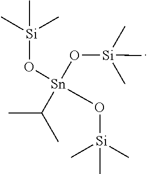

13. The method of claim 1, wherein the mono-substituted tin silanolate compound is a compound of the formula:

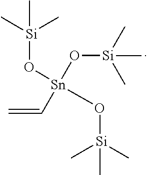

14. A composition comprising:
a mono-substituted tin silanolate compound of the formula:
RSn(OSiR²₃)₃,
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; and
R² is independently at least one of a hydrogen, a halide, an alkyl, an alkenyl, an alkynyl, a cycloalkyl, an aryl, an aralkyl, an alkaryl, or a haloalkyl.

15. The composition of claim 14, wherein the mono-substituted tin silanolate compound is a compound of the formula: 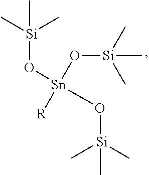
where:
R is —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃)CH₂CH₃, —CH₂CH(CH₃)₂, —C(CH₃)₃, —(CH₂)₃CH₃, —C₆H₅, —CH₂(C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, or —Si(CH₃)₃.

16. The composition of claim 14, wherein the mono-substituted tin silanolate compound is a compound of the formula:

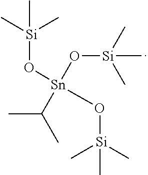

17. The composition of claim 16, wherein a purity of the mono-substituted tin silanolate compound is at least 99.9%.

18. The composition of claim 14, wherein the mono-substituted tin silanolate compound is a silanolate compound of the formula:

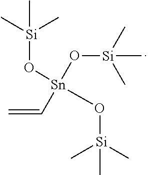

19. The composition of claim 18, wherein a purity of the mono-substituted tin silanolate compound is at least 80%.

20. The composition of claim 14, wherein a purity of the mono-substituted tin silanolate compound is at least 99.9%.
